(19) United States
(12) Patent Application Publication
(10) Pub. No.: US 2013/0112459 A1
(43) Pub. Date: May 9, 2013

(54) LAMINATE BODY, LAMINATE PLATE, MULTILAYER LAMINATE PLATE, PRINTED WIRING BOARD, AND METHOD FOR MANUFACTURE OF LAMINATE PLATE

(71) Applicant: HITACHI CHEMICAL COMPANY, LTD., Tokyo (JP)

(72) Inventors: Masahiro AOSHIMA, Ibaraki (JP); Yoshihiro Takahashi, Ibaraki (JP); Yuka Yamazaki, Saitama (JP); Yasuo Kamigata, Ibaraki (JP); Hikari Murai, Ibaraki (JP)

(73) Assignee: HITACHI CHEMICAL COMPANY, LTD., Tokyo (JP)

(21) Appl. No.: 13/624,099

(22) Filed: Sep. 21, 2012

Related U.S. Application Data
(60) Provisional application No. 61/537,902, filed on Sep. 22, 2011.

(30) Foreign Application Priority Data
Sep. 12, 2012 (JP) 2012-200932

(51) Int. Cl. B32B 17/06; B05D 3/00; B32B 37/00; H05K 1/03

(52) U.S. Cl. CPC B32B 17/064; H05K 1/0306; B05D 3/007; B32B 37/00
USPC 174/255; 428/426; 428/337; 428/339; 428/436; 428/435; 428/425.6; 428/430; 428/441; 428/429; 428/432; 428/427; 427/385.5; 156/285; 156/60

(57) ABSTRACT

A laminate body containing at least two glass substrate layers and at least one inner resin composition layer existing between the adjacent two glass substrate layers, wherein the inner resin composition layer comprises an inner resin composition that contains a thermosetting resin and an inorganic filler. A laminate plate containing at least two glass substrate layers and at least one inner cured resin layer existing between the adjacent two glass substrate layers, wherein the inner cured resin layer comprises a cured product of an inner resin composition that contains a thermosetting resin and an inorganic filler. A printed wiring board having the laminate plate and a wiring provided on the surface of the laminate plate. A method for producing the laminate plate, which comprises a cured resin layer forming step of forming a cured resin layer on the surface of a glass substrate.

### TECHNICAL FIELD

The present invention relates to a laminate body and a laminate plate suitable for use in semiconductor packages and printed wiring boards, to a printed wiring board and a multilayer laminate plate using the laminate plate, and to a method for producing the laminate plate.

### BACKGROUND ART

Recently, the demand for thinner and lighter electronic instruments has become increasingly greater, and thinning and densification of semiconductor packages and printed wiring boards has been promoted. For stably packaging electronic parts with satisfying the demand for thinning and densification thereof, it is important to prevent the warping to occur in packaging.

In packaging, one reason for the warping to occur in semiconductor packages is the difference in the thermal expansion coefficient between the laminate plate used in a semiconductor package and the silicon chips to be mounted on the surface of the laminate plate. Accordingly, for the laminate plate for semiconductor packages, efforts are made to make the thermal expansion coefficient of the laminate plate nearer to the thermal expansion coefficient of the silicon chips to be mounted thereon, or that is, to lower the thermal expansion coefficient of the laminate plate. Another reason is that the elastic modulus of the laminate plate is low, for which, therefore, it may be effective to increase the elastic modulus of the laminate plate. To that effect, for reducing the warping of a laminate plate, it is effective to lower the expansion coefficient of the laminate plate and to increase the elastic modulus thereof.

Various methods may be taken into consideration for lowering the thermal expansion coefficient of a laminate plate and for increasing the elastic modulus thereof; and among them there is known a method of lowering the thermal expansion coefficient of the resin for laminate plates and increasing the fill ration with an inorganic filler to be in the resin. In particular, high-rate filling with an inorganic filler is a method by which reduction in the thermal expansion coefficient and also enhancement of heat resistance and flame retardance could be expected (Patent Reference 1). However, it is known that increasing the inorganic filler content results in insulation reliability degradation, adhesiveness failure between resin and the wiring layer to be formed on the surface thereof, and pressing failure in laminate plate production, and increasing the filler content is therefore limited.

Some approaches have been tried to attain the intended purpose of thermal expansion coefficient reduction through selection or modification of resin. For example, a method of increasing the crosslinking density of the resin for wiring boards to thereby increase Tg thereof and to reduce the thermal expansion coefficient thereof is generally employed in the art (Patent References 2 and 3). However, increasing the crosslinking density is to shorten the molecular chain between functional groups, but shortening the molecular chain to a level overstepping a certain threshold is limitative in view of the reactivity of the resin, and may often bring about a problem in that the resin strength would be lowered. Consequently, there is also a limit on lowering the thermal expansion coefficient according to the method of increasing the crosslinking density.

As in the above, for conventional laminate plates, lowering the thermal expansion coefficient thereof and increasing the elastic modulus thereof have heretofore been tried by increasing the fill ration of the inorganic filler therein and by employing a resin having a low thermal expansion coefficient; however, these are being pushed to the limit.

As a method differing from the above, there has been made a trial of using a glass film as a layer having a thermal expansion coefficient almost the same as the thermal expansion coefficient of electronic parts (silicon chips) and laminating a resin on the glass film by pressing to thereby reduce the thermal shock stress of the resulting laminate (Patent Reference 4); however, the elastic modulus of the resin layer is low and the thermal expansion coefficient thereof is high, and therefore the method is insufficient for realizing the reduction in the warp of substrate.

### CITATION LIST

### Patent References

[Patent Reference 1] JP-A 2004-182851
[Patent Reference 2] JP-A 2000-243864
[Patent Reference 3] JP-A 2000-114727
[Patent Reference 4] Japanese Patent No. 4657554

### SUMMARY OF THE INVENTION

### Problems that the Invention is to Solve

As described above, the substrate obtained according to the production method in Patent Reference 4 still has a low elastic modulus and a high thermal expansion coefficient, and is therefore insufficient for realizing the reduction in the warp of substrate.

The present invention has been made in consideration of the situation as above, and its object is to provide a laminate plate and a multilayer laminate plate which have a low thermal expansion coefficient and a high elastic modulus, which can be prevented from warping and which hardly crack, to provide a laminate body suitable for producing the laminate plate and the multilayer laminate plate, to provide a printed wiring board using the laminate plate and the multilayer laminate plate, and to provide a production method for the laminate plate.

### Means for Solving the Problems

Patent Reference 4 has no description at all relating to adding an inorganic filler to the resin for the substrate produced by laminating the resin on a glass film. From the description in Patent Reference 4, it is considered that incorporating an inorganic filler to the resin should be evaded.

Specifically, in Patent Reference 4, one indispensable constituent feature is that the thermal expansion action of the entire substrate is substantially determined by the glass film (Claim 1 in Patent Reference 4). In view of this, the influence of the resin on the thermal expansion action of the substrate must be as small as possible, and for this, the modulus of elasticity of the resin must be kept as low as possible (in case where the resin has a high elastic modulus, the resin having such a high elastic modulus would have a great influence on the thermal expansion action of the entire substrate). On the other hand, when an inorganic filler is incorporated in the resin, then the resin may have an increased elastic modulus. Accordingly, from the description in Patent Reference 4, incorporating an inorganic filler to the resin must be evaded.

In addition, when an inorganic filler is incorporated in the resin in Patent Reference 4, it may be considered that the glass substrate may be broken with ease, as starting from the inorganic filler therein. From this viewpoint, it is presumed that incorporating an inorganic filler in the resin would be evaded in Patent Reference 4.

At present, there exists no case of incorporating an inorganic filler in a resin layer in a laminate plate of a glass substrate layer and a resin layer as in Patent Reference 4.

Surprisingly, however, as a result of assiduous studies made for solving the above-mentioned problems, the present inventors have found that, in a laminate plate containing a cured resin layer and a glass substrate layer, when an inorganic filler is incorporated in the cured resin layer, then there can be obtained a laminate plate which has a low thermal expansion coefficient and a high elastic modulus, which is prevented from warping and which hardly cracks.

The present invention has been made on the basis of the finding as above, and includes the following [1] to [12] as the gist thereof.

[1] A laminate body containing at least two glass substrate layers and at least one inner resin composition layer existing between the adjacent two glass substrate layers, wherein the inner resin composition layer comprises an inner resin composition that contains a thermosetting resin and an inorganic filler.
[2] The laminate body according to [1], wherein the thickness of the glass substrate layer is from 30 μm to 200 μm.
[3] The laminate body according to [1] or [2], wherein the outermost surface layer and the outermost back layer are the glass substrate layers.
[4] The laminate body according to [1] or [2], which has an outer resin composition layer on the more surface side than the glass substrate layer on the outermost surface side and on the more back side than the glass substrate layer on the outermost back side of at least the two glass substrate layers.
[5] The laminate body according to [4], wherein the outer resin composition layer has a thickness of from 3 to 40 μm.
[6] The laminate body according to any of [1] to [5], wherein the thermosetting resin is one or more selected from an epoxy resin, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin and a melamine resin.
[7] The laminate body according to any of [1] to [6], wherein the inorganic filler is one or more selected from silica, alumina, talc, mica, aluminium hydroxide, magnesium hydroxide, calcium carbonate, aluminium borate and borosilicate glass.
[8] A laminate plate containing at least two glass substrate layers and at least one inner cured resin layer existing between the adjacent two glass substrate layers, wherein the inner cured resin layer comprises a cured product of an inner resin composition that contains a thermosetting resin and an inorganic filler.
[9] The laminate plate according to [8], which has a storage elastic modulus at 40° C. of from 10 GPa to 70 GPa.
[10] The laminate plate according to [8] or [9], which is obtained by heating the laminate body of any of [1] to [7].
[11] A multilayer laminate plate containing multiple laminate plates, wherein at least one laminate plate is the laminate plate of any of [8] to [10].
[12] A printed wiring board having the laminate plate of any of [8] to [10] and a wiring provided on the surface of the laminate plate.
[13] A printed wiring board having the multilayer laminate plate of [11] and a wiring provided on the surface of the multilayer laminate plate.
[14] A method for producing the laminate plate of any of [8] to [10], which comprises a cured resin layer forming step of forming a cured resin layer on the surface of a glass substrate.
[15] The method for producing a laminate plate according to [14], wherein the cured resin layer forming step is a step of applying the resin composition onto the glass substrate followed by drying and curing it.
[16] The method for producing a laminate plate according to [14], wherein the cured resin layer forming step is a step of laminating a film of the resin composition onto the glass substrate by the use of a vacuum laminator or a roll laminator followed by curing it.
[17] The method for producing a laminate plate according to [14], wherein the cured resin layer forming step is a step of arranging a film of the resin composition on the glass substrate followed by pressing and curing it.

### Advantage of the Invention

According to the invention, there are provided a laminate plate and a multilayer laminate plate which have a low thermal expansion coefficient and a high elastic modulus, which can be prevented from warping and which hardly crack, a laminate body favorable for production of the laminate plate and the multilayer laminate plate, a printed wiring board using the laminate plate and the multilayer laminate plate, and a method for producing the laminate plate.

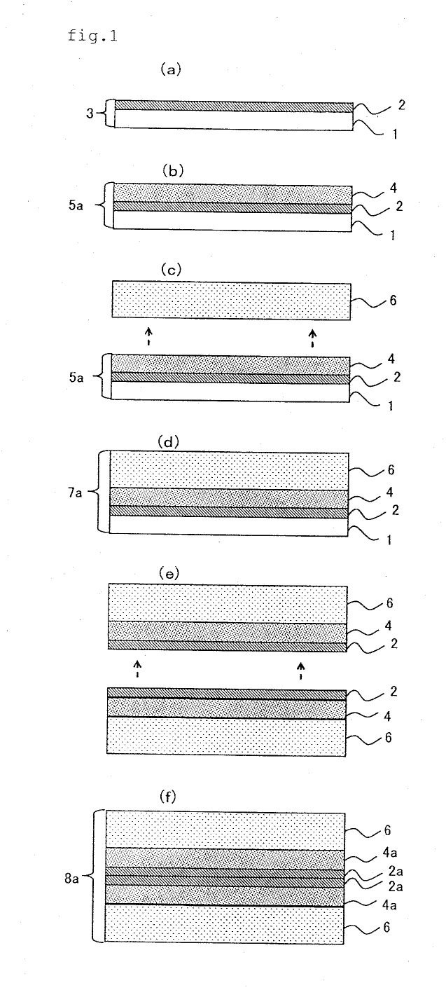

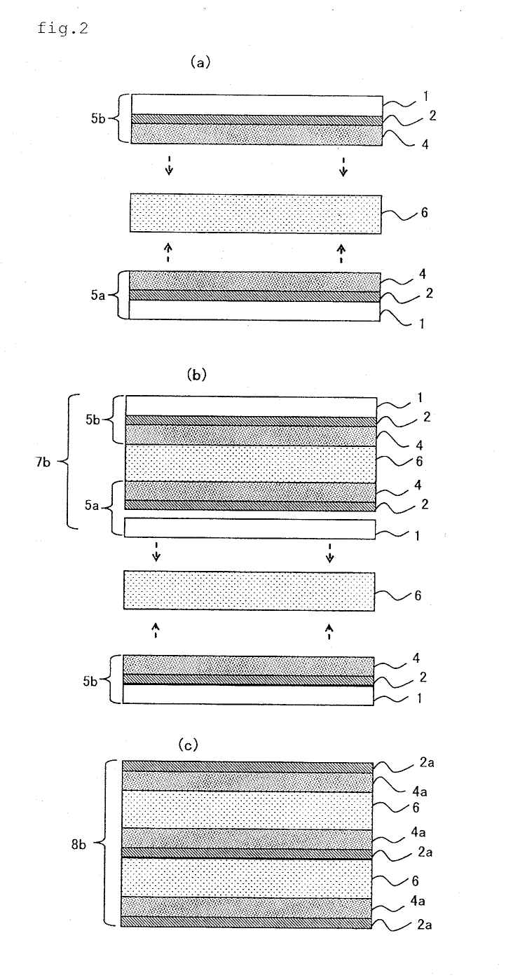

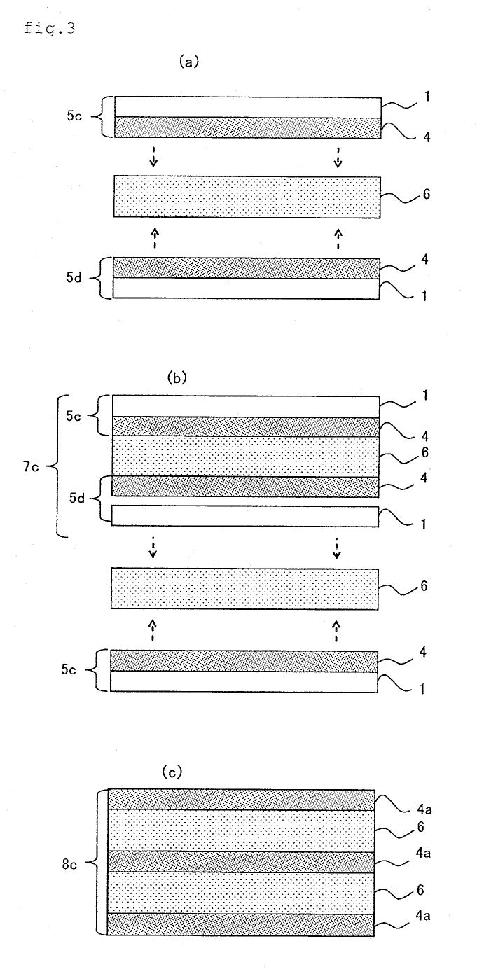

### BRIEF DESCRIPTION OF THE DRAWINGS

[FIG. 1] This is a schematic cross-sectional view of explaining the production method of Example 1.

[FIG. 2] This is a schematic cross-sectional view of explaining the production method of Example 2.

[FIG. 3] This is a schematic cross-sectional view of explaining the production method of Example 3.

### MODE FOR CARRYING OUT THE INVENTION

The laminate body, the laminate plate, the multilayer laminate plate, the printed wiring board, and the method for producing the laminate plate of the present invention are described in detail hereinunder.

In the present invention, the laminate body means one in which the constituent component of the thermosetting resin is uncured or semi-cured; and the laminate plate means one in which the constituent component of the thermosetting resin has been cured.

### [Laminate Body]

The laminate body of the present invention contains at least two glass substrate layers and at least one inner resin composition layer existing between the adjacent two glass substrate layers, wherein the inner resin composition layer comprises an inner resin composition that contains a thermosetting resin and an inorganic filler.

Preferably, the size of the laminate body of the present invention is selected within a range where the width is from 10 mm to 1000 mm and the length is from 10 mm to 3000 mm (in case where the laminate body is used as a roll, its length may be suitably applied thereto) from the viewpoint of the handleability thereof. More preferably, the size is within a range where the width is from 25 mm to 550 mm and the length is from 25 mm to 550 mm.

The thickness of the laminate body of the present invention is selected preferably within a range of from 35 μm to 20 mm, depending on the use thereof. More preferably, the thickness of the laminate body is from 50 to 1000 μm, even more preferably from 100 to 500 μm, still more preferably from 120 to 300 μm, further more preferably from 130 to 200 μm.

The laminate body of the present invention contains at least two glass substrate layers and at least one inner resin composition layer existing between the adjacent two glass substrate layers, wherein the inner resin composition layer comprises an inner resin composition that contains thermosetting resin and an inorganic filler.

The laminate plate that is obtained by curing the inner resin composition layer in the laminate body of the present invention to give an inner cured resin layer has glass substrate layers each having a low thermal expansion coefficient and a high elastic modulus on the same level as that of silicon chips, and therefore the laminate plate may have a low thermal expansion coefficient and a high elastic modulus; and consequently, the laminate plate is prevented from warping and hardly cracks. In particular, the laminate plate has glass substrate layers having high heat resistance, and therefore noticeably has low thermal expansivity in the temperature region of from 100° C. to lower than Tg of the inner cured resin layer. In addition, the inner cured resin layer contains an inorganic filler, and therefore the inner cured resin layer can have a low thermal expansion coefficient and a high elastic modulus; and consequently, the laminate plate containing the inner cured resin layer can have a lower thermal expansion coefficient and a higher elastic modulus. Further, the laminate body of the present invention has at least two glass substrate layers and has at least one inner resin Composition layer between the arbitrary glass substrate layers, and therefore, when the laminate body is processed into the corresponding laminate plate in the manner as above, it can have a lower thermal expansion coefficient and a higher elastic modulus than in the case of a laminate body that has one glass substrate layer having the same thickness as the total thickness of all the glass substrate layers in the laminate body of the present invention.

### <Laminate Configuration of Laminate Body>

Not specifically defined, the laminate configuration of the laminate body may be any one having at least one inner resin composition layer existing between arbitrary two glass substrate layers.

### <<First Laminate Configuration>>

For example, the configuration may be such that the layer on the outermost surface side and the layer on the outermost back side of the laminate body are glass substrate layers. Examples of the configuration of the type are shown below.

“(Glass substrate layer/inner resin composition layer)ₘ/glass substrate layer” (where m is an integer of 1 or more); and for example, the configurations where m is any of 1 and 2 are as follows:

“Glass substrate layer/inner resin composition layer/glass substrate layer”;

“Glass substrate layer/inner resin composition layer/glass substrate layer/inner resin composition layer/glass substrate layer”.

### <<Second Laminate Configuration>>

On the other hand, for example, the configuration may be so designed as to have an outer resin composition layer on the more surface side than the glass substrate layer on the outermost surface side and on the more back side than the glass substrate layer on the outermost back side of at least the above-mentioned two glass substrate layers. Examples of the configuration of the type are shown below.

“Outer resin composition layer/(glass substrate layer/inner resin Composition layer)n/glass substrate layer/outer resin composition layer” (where n is an integer of 1 or more); and for example, the configurations where n is any of 1 and 2 are as follows:

“Outer resin composition layer/glass substrate layer/inner resin composition layer/glass substrate layer/outer resin composition layer”;

“Outer resin composition layer/glass substrate layer/inner resin composition layer/glass substrate layer/inner resin composition layer/glass substrate layer/outer resin composition layer”.

Having the configuration as above, the glass substrate layer is prevented from being exposed out of the laminate body to be in direct contact with any external substance, and therefore the glass substrate layer can be prevented from cracking and the handleability (easiness in handling) of the laminate body can be thereby improved. In addition, conductor layer of a metal foil, plating or the like to be mentioned below may be formed directly on the laminate body or the laminate plate.

The inner resin composition layer and the outer inner composition layer may be referred to as “resin composition layer”; and the inner resin composition and the outer resin composition may be referred to as “resin composition”. The inner cured resin layer and the outer cured resin layer to be formed by curing the inner resin composition layer and the outer inner composition layer, respectively, may be referred to as “cured resin layer”; and the inner cured resin and the outer cured resin may be referred to as “cured resin”.

### <Inner Resin Composition>

The inner resin composition contains a thermosetting resin and an inorganic filler.

### <<Thermosetting Resin>>

Not specifically defined, the thermosetting resin includes, for example, an epoxy resin, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin and a melamine resin. Of those, preferred are an epoxy resin and a cyanate resin as excellent in moldability and electric insulation quality.

The epoxy resin includes, for example, bisphenol A-type epoxy resin, bisphenol F-type epoxy resin, bisphenol S-type epoxy resin, phenol-novolak-type epoxy resin, cresol-novolak-type epoxy resin, bisphenol A-novolak-type epoxy resin, bisphenol F-novolak-type epoxy resin, stilbene-type epoxy resin, triazine skeleton-containing epoxy resin, fluorene skeleton-containing epoxy resin, triphenolphenolmethane-type epoxy resin, biphenyl-type epoxy resin, xylylene-type epoxy resin, biphenylaralkyl-type epoxy resin, naphthalene-type epoxy resin, dicyclopentadiene-type epoxy resin, alicyclic epoxy resin, diglycidyl ether compound of polyfunctional phenol and polycyclic aromatic compound such as anthracene, etc. Further mentioned are phosphorus-containing epoxy resins produced by introducing a phosphorus compound into these epoxy resins. Of those, preferred are biphenylaralkyl-type epoxy resin and naphthalene-type epoxy resin from the viewpoint of the heat resistance and the flame retardance thereof. One alone or two or more of these may be used here as combined.

The cyanate resin includes, for example, bisphenol-type cyanate resins such as novolak-type cyanate resin, bisphenol A-type cyanate resin, bisphenol E-type cyanate resin, tetramethylbisphenol F-type cyanate resin, etc., and their partially-triazinated prepolymers. Of those, preferred is novolak-type cyanate resin from the viewpoint of the heat resistance and the flame retardance thereof. One alone or two or more of these may be used here as combined.

The content of the thermosetting resin to be contained in the inner resin composition is preferably within a range of from 20 to 80% by mass relative to the mass to be obtained by subtracting the content of the inorganic filler from the total amount of the inner resin composition.

### <<Inorganic Filler>>

The inorganic filler includes, for example, silica, alumina, talc, mica, aluminium hydroxide, magnesium hydroxide, calcium carbonate, aluminium borate and borosilicate glass.

Of those, preferred is silica from the viewpoint of the low thermal expansivity thereof, and more preferred is spherical amorphous silica of which the thermal expansion coefficient is 0.6 ppm/K or so and is extremely small and of which the flowability reduces little when highly filled in resin.

The spherical amorphous silica is preferably one having a cumulative 50% particle diameter of from 0.01 to 10 μm, more preferably from 0.03 to 5 μm.

The cumulative 50% particle diameter as referred to herein means the particle diameter of a powder at the point corresponding to just the 50% volume based on the total volume 100% of the powder, as read on the particle-size cumulative frequency distribution curve thereof; and this may be determined according to a laser diffractive scattering method using a particle size distribution analyzer, etc.

The content of the inorganic filler in the inner resin composition is preferably from 5 to 75% by volume of the inner resin composition, more preferably from 15 to 70% by volume, even more preferably from 30 to 70% by volume. When the content of the inorganic filler is from 5 to 75% by volume of the inner resin composition, then the thermal expansion coefficient of the composition may be sufficiently lowered and the composition may have a suitable flowability and may be excellent in moldability. Specifically, when the content of the inorganic filler is at least 5% by volume, then the thermal expansion coefficient of the composition may be sufficiently lowered; and when at most 75% by volume, then the flowability of the composition can increase and the moldability thereof can be thereby bettered.

For expression in terms of % by mass for, for example, silica as the inorganic filler, the silica content in the resin composition is preferably from 8 to 85% by mass of the inner resin composition, more preferably from 24 to 82% by mass, even more preferably from 44 to 82% by mass.

Using silica having a mean primary particle diameter of at most 1 μm (nanosilica) as the inorganic filler makes it possible to form a microwiring on the cured resin layer of the laminate plate. Nanosilica is preferably one having a specific surface area of at least 20 m²/g. From the viewpoint of reducing the surface profile after roughening treatment in the plating process for the laminate plate, the mean primary particle diameter is preferably at most 100 nm. The specific surface area can be measured according to a BET method.

The “mean primary particle diameter” as referred to herein means a mean particle diameter of the non-aggregated simple particle, and does not mean the mean diameter of aggregated particles, or that is, the secondary particle diameter thereof. The mean primary particle diameter can be determined, for example, by analyzing the powder with a laser diffractive particle sizer. As the inorganic filler of the type, preferred is fumed silica.

Further, the inorganic filler is preferably treated with a surface treatment agent such as a silane coupling agent or the like for enhancing the moisture resistance thereof, and is also preferably hydrophobized for enhancing the dispersibility thereof.

In case where a microwiring is formed on the cured resin layer of the laminate plate, the content of the inorganic filler is preferably at most 20% by mass of the resin composition. When the content is at most 20% by mass, then the layer can keep the good surface profile after roughening treatment and the plating characteristics thereof and also the interlaminar insulation reliability thereof can be prevented from worsening. On the other hand, it is expected that, by incorporating the inorganic filler thereinto, the thermal expansivity of the resin composition could be reduced and the elastic modulus thereof could be increased, and therefore, in case where weight is given to the thermal expansivity reduction and the elastic modulus increase along with to the microwiring formation, the content of the inorganic filler is preferably from 3 to 20% by mass, more preferably from 5 to 20% by mass.

### <<Other Components>>

In addition to the above-mentioned components, a curing agent, a curing promoter, a thermoplastic resin, an elastomer, a flame retardant, a UV absorbent, an antioxidant, a photopolymerization initiator, a fluorescent brightener, an adhesiveness improver and the like may be added to the inner resin composition.

For example, in case where an epoxy resin is used, examples of the curing agent include polyfunctional phenol compounds such as phenol-novolak, cresol-novolak, etc.; amine compounds such as dicyandiamide, diaminodiphenylmethane, diaminodiphenyl sulfone, etc.; acid anhydrides such as phthalic anhydride, pyromellitic anhydride, maleic anhydride, maleic anhydride copolymer, etc.; and polyimides. Different types of these curing agents may be used as combined.

Examples of the curing promoter, for example, for epoxy resin include, imidazoles and their derivatives; organic phosphorus compounds; secondary amines, tertiary amines, and quaternary ammonium salts.

Examples of the UV absorbent include benzotriazole-type UV absorbents.

The antioxidant includes hindered phenol-type or styrenated phenol-type antioxidants.

Examples of the photopolymerization initiator include benzophenones, benzyl ketals, thioxanthone-type photopolymerization initiators, etc.

Examples of the fluorescent brightener include stilbene derivatives and the like fluorescent brighteners.

Examples of the adhesiveness improver include urea compounds such as ureasilane, etc.; silane coupling agents and the like adhesiveness improvers.

### <Inner Resin Composition Layer>

The inner resin composition layer comprises the above-mentioned inner resin composition. The inner resin composition layer includes not only an uncured inner resin composition but also a semi-cured inner resin composition.

Preferably, the size of the inner resin composition layer in the present invention is selected within a range where the width is from 10 mm to 1000 mm and the length is from 10 mm to 3000 mm (in case where the laminate body is used as a roll, its length may be suitably applied thereto). More preferably, the size is within a range where the width is from 25 mm to 550 mm and the length is from 25 mm to 550 mm from the viewpoint of the handleability of the layer.

Preferably, the thickness of the inner resin composition layer in the present invention is selected within a range of from 3 μm to 200 μm/layer. From the viewpoint of lowering the thermal expansion coefficient of the laminate body and the laminate plate and increasing the elastic modulus thereof, the thickness of the inner resin composition is preferably from 3 to 150 μm/layer, more preferably from 3 to 100 μm, still more preferably from 3 to 50 μm, furthermore preferably from 3 to 40 μm.

### <Outer Resin Composition>

The material of the outer resin composition to constitute the outer resin composition layer is not specifically defined, for which, for example, usable is the same as that of the above-mentioned inner resin composition. As the thermosetting resin, also usable is one excellent in adhesiveness to conductor layer, or one excellent in desmearing resistance in the desmearing treatment to be mentioned below. The same as the inner resin composition but not containing the inorganic filler is also usable.

### <Outer Resin Composition Layer>

For enhancing the cracking resistance and the handleability (easiness in handling) of the glass substrate layer, the thickness of the outer resin composition layer is preferably at least 3 μm. On the other hand, for securing the low thermal expansion coefficient and the high elastic modulus of the laminate plate to be produced by curing the outer resin composition layer, the thickness of the outer resin composition layer is preferably at most 40 μm. From these viewpoints, the thickness of the outer resin composition layer is preferably from 3 to 40 μm, more preferably from 5 to 30 μm, even more preferably from 10 to 20 μm.

### <Glass Substrate Layer>

For the purpose of thinning the laminate body and from the viewpoint of the workability thereof, the thickness of the glass substrate layer is preferably from 15 to 100 μm/layer; and in consideration of the easiness in handling it and of the practicability thereof, the thickness is more preferably from 25 to 75 μm, even more preferably from 40 to 60 μm.

From the same viewpoints as above, the total thickness of the glass substrate layers existing in the laminate body is preferably from 30 to 200 μm; and in consideration of the easiness in handling the laminate body and of the practicability thereof, the total thickness is more preferably from 50 to 150 μm, even more preferably from 80 to 120 μm.

The thickness of the glass substrate layer as referred to herein indicates the mean thickness of the glass substrate layer. The mean thickness of the glass substrate layer may be determined by the use of any known thickness measuring device such as a micrometer, a thickness gauge or the like. For example, for a rectangular or square glass substrate layer, the thickness thereof is measured at four corners and at the center thereof with a micrometer, and the mean value of the found data is referred to as the mean thickness of the glass substrate layer.

The material of the glass substrate layer may be glass such as alkali silicate glass, alkali-free glass, quartz glass or the like, but from the viewpoint of the low thermal expansivity thereof, preferred is borosilicate glass.

Preferably, the size of the glass substrate layer in the present invention is selected within a range where the width is from 10 mm to 1000 mm and the length is from 10 mm to 3000 mm (in case where the laminate body is used as a roll, its length may be suitably applied thereto). More preferably, the width is within a range of from 25 mm to 550 mm and the length is from 25 mm to 550 mm from the viewpoint of the handleability of the layer.

The thermal expansion coefficient of the glass substrate layer is preferably nearer to the thermal expansion coefficient (3 ppm/° C. or so) of silicon chips since the laminate body or the laminate plate to be obtained from the laminate body can be well prevented from warping, and is more preferably at most 8 ppm/° C., even more preferably at most 6 ppm/° C., still more preferably at most 4 ppm/° C.

The storage elastic modulus at 40° C. of the glass substrate layer is preferably larger, and is more preferably at least 20 GPa, even more preferably at least 25 GPa, still more preferably at least 30 GPa.

Preferably, the glass substrate layer accounts for from 10 to 95% by volume of the entire laminate body, more preferably from 15 to 90% by volume, even more preferably from 20 to 85% by volume, still more preferably from 40 to 80% by volume, further more preferably from 50 to 75% by volume, even further more preferably from 53 to 74% by volume. When the content of the glass substrate is at least 10% by volume, then it is advantageous for attaining low thermal expansivity and high elasticity; but on the contrary, when the content of the glass substrate is at most 95% by volume, then it is advantageous in point of the workability and the handleability (easiness in handling) of the laminate body.

### <Adhesive Layer>

The laminate body of the present invention has an inner resin composition layer containing a thermosetting resin and an inorganic filler, and in addition thereto, may further have an adhesive layer containing a thermosetting resin but not containing an inorganic filler. The adhesive layer is arranged, for example, between the glass substrate layer and the inner resin composition layer, and is used for the purpose of enhancing the adhesiveness between the two layers.

### <Proportion of Layers in Laminate Body>

Preferably, in the present invention, the inner resin composition layer accounts for from 5 to 60% by volume relative to the entire laminate body from the viewpoint of obtaining a laminate plate having a low thermal expansion coefficient and having a high elastic modulus, more preferably from 10 to 55% by volume, even more preferably from 10 to 50% by volume, still more preferably from 10 to 45% by volume.

The glass substrate layer in the present invention is as described above.

In case where the laminate body has an outer resin composition layer, preferably, the outer resin composition layer accounts for from 1 to 35% by volume relative to the entire laminate body, more preferably from 5 to 30% by volume, even more preferably from 10 to 25% by volume.

In case where the laminate body has an adhesive layer, preferably, the adhesive layer accounts for from 1 to 20% by volume relative to the entire laminate body, more preferably from 2 to 15% by volume, even more preferably from 3 to 10% by volume.

### <Support Film and Protective Film>

The above-mentioned laminate body may have a support film and a protective film on the surface thereof. The support film and the protective film are described in detail in the next section of the description of the production method for the laminate body.

### [Production Method for Laminate Body]

The production method for the laminate body is not specifically defined. The laminate body may be produced by lamination of a film of an inner resin composition or an outer resin composition onto a glass substrate, or by coating a glass substrate with an inner resin composition or an outer resin composition, etc. Of those, the lamination method is preferred as the product is easy to produce.

Next, the production method is described in detail.

### <Production Method for Laminate Body by Lamination>

The above-mentioned laminate body is favorably produced through pressure lamination such as vacuum lamination or roll lamination, in which an adhesive film using the above-mentioned inner resin composition or outer resin composition is laminated on a glass substrate. The adhesive film is described below. For the vacuum lamination or roll lamination, usable is any commercially-available vacuum laminator or roll laminator.

The thermosetting resin in the above-mentioned inner resin composition or outer resin composition and the interlaminar insulation composition mentioned above are preferably those capable of melting at a temperature not higher than the temperature in lamination. For example, lamination with a vacuum laminator or a roll laminator is generally carried out at 140° C. or lower, and therefore, the thermosetting resin in the above-mentioned inner resin composition or outer resin composition is preferably one capable of melting at 140° C. or lower.

First, the adhesive film is described, and then the lamination method using the adhesive film is described.

### <<Adhesive Film>>

In case where the laminate body is produced by the use of a vacuum laminator or a pressure laminator, in general, the above-mentioned inner resin composition or outer resin composition is prepared as an adhesive film thereof.

As the adhesive film for use in the present invention, Preferred are those having a laminate configuration mentioned below.

(1) Support film/inner (or outer) resin composition layer
(2) Support film/inner (or outer) resin composition layer/inner (or outer) resin composition layer

Also preferred for use herein are those prepared by further laminating a protective film on the laminate configuration of the above (1) and (2) and having a laminate configuration mentioned below.

(3) Support film/inner (or outer) resin composition layer/protective film
(4) Support film/inner (or outer) resin composition layer/inner (or outer) resin composition layer/protective film

The protective film is used for preventing the resin composition layer from being contaminated with impurities or from being flawed.

One derived from the adhesive film by removing the support film and the protective film therefrom may be referred to as an adhesive film body. Any other configuration than the above-mentioned cases is employable here, in which an interlaminar insulation composition can be arranged between a conductor layer and the laminate body of the present invention, and the invention is not specifically limited to the above-mentioned cases.

The adhesive film having the laminate configuration of the above (1) to (4) may be produced according to any method known to those skilled in the art.

One example of producing the adhesive film of the above (1) comprises dissolving the above-mentioned inner (or outer) resin composition in an organic solvent to prepare a varnish with the inorganic filler dispersed therein. Next, the varnish is applied to a support film that serves as a support, and then the organic solvent is evaporated away by heating, hot air blowing or the like, thereby forming the inner (or outer) resin composition layer.

One example of producing the adhesive film of (2) comprises forming an inner (or outer) resin composition layer in the same manner as in (1) on the surface of the inner for outer) resin composition layer formed on the support as in the above (1).

One example of producing the adhesive film of (3) comprises dissolving the above-mentioned inner (or outer) resin composition in an organic solvent to prepare a varnish with the inorganic filler dispersed therein. Next, the varnish is applied to one of a support film and a protective film, then the other of the support film and the protective film is arranged on the varnish, and the organic solvent is evaporated away by heating, hot air blowing or the like, thereby forming the inner (or outer) resin composition layer.

One example of producing the adhesive film of the above (4) comprises applying the above-mentioned varnish onto the surface of the inner (or outer) resin composition layer formed on the support as in the above (1), then arranging the other of the support film and the protective film on the varnish, and evaporating the organic solvent by heating, hot air blowing or the like to thereby form the inner (or outer) resin composition layer.

Another example of producing the adhesive film of the above (4) comprises forming the inner (or outer) resin composition layer on a protective film according to the same process as in (1) except that a protective film is used in place of the support film, then arranging the inner (or outer) resin composition layer of the adhesive film produced in the manner as in the above (1) to be in contact with that inner (or outer) resin composition layer, and thereafter laminating these by the use of a pressure laminator such as a vacuum laminator or a roll laminator to be mentioned below.

As the coating apparatus for the inner resin composition layer and the outer resin composition layer, herein employable is any coating apparatus known to those skilled in the art, such as a comma coater, a bar coater, a kiss coater, a roll coater, a gravure coater, a die coater, etc. It is desirable that the coating apparatus is suitably selected depending on the thickness of the film to be formed.

In the above-mentioned adhesive film, the inner resin composition layer and the outer resin composition layer may be semi-cured.

The support film serves as a support in producing the adhesive film, and when a multilayer printed wiring board is produced, in general, it is finally peeled off or removed.

As the support film, for example, there may be mentioned polyolefins such as polyethylene, polyvinyl chloride, etc.; polyesters such as polyethylene terephthalate (hereinafter this may be abbreviated as “PET”), polyethylene naphthalate, etc.; polycarbonates, polyimides; and further release paper, as well as metal foils such as copper foil, aluminium foil, etc. In case where a copper foil is used as the support film, the copper film may be used as a conductor layer directly as it is for circuit formation. In this case, as the copper foil, there are mentioned rolled copper, electrolytic copper foil, etc., and in general, those having a thickness of from 2 μm to 36 μm are used. In case where a thin copper foil is used, a carrier-supported copper foil may be used for enhancing the workability thereof.

The support film may be mat-treated, corona-treated and also lubrication-treated.

The thickness of the support film is generally from 10 μm to 150 μm, preferably from 25 to 50 μm. When thinner than 10 μm, the film would be difficult to handle. On the other hand, the support film is, in general, peeled off or removed before use, as described above, and therefore, when the thickness thereof is more than 150 μm, it is unfavorable from the viewpoint of energy saving.

The above-mentioned protective film is peeled off before lamination or hot pressing. The material of the protective film may be the same as that of the support film, or may differ from the latter. Not specifically defined, the thickness of the protective film may be on the same level as that of the support film, but is preferably within a range of from 1 to 40 μm.

### <<Lamination Method Using the Above-Mentioned Adhesive Film>>

Next described is one example of the lamination method using the above-mentioned adhesive film.

The support film is removed from the adhesive film, and when the adhesive film further has a protective film, the protective film is removed therefrom to give the adhesive film body. However, the protective film or the support film to constitute the outermost surface of the stacked structure to be mentioned below may be left as such.

Next, the adhesive film body and a glass substrate layer are stacked in such a manner that the adhesive film body and the glass substrate layer are arranged in the above-mentioned first lamination configuration or second lamination configuration to prepare a stacked structure, and these are laminated under pressure while the adhesive film body is kept pressurized and heated. Regarding the lamination condition, preferably, the adhesive film body and the glass substrate are optionally pre-heated and then laminated at a bonding temperature (lamination temperature) of preferably from 60° C. to 140° C. and under a lamination pressure of preferably from 1 to 11 kgf/cm². In case where a vacuum laminator is used, preferably, the lamination is attained under a reduced pressure of a pneumatic pressure of at most 20 mmHg (26.7 hPa). The lamination method may be in a batch mode or in a continuous mode with rolls.

Afterwards, this is cooled to around room temperature to give a laminate body.

### <Production Method for Laminate Body by Coating>

The production method for the laminate body by coating is not specifically defined. For example, the above-mentioned inner (or outer) resin composition is dissolved in an organic solvent to prepare a varnish with the inorganic filler dispersed therein. The varnish is applied onto at least one of glass substrates, and at least two of these glass substrates are stacked up in such a manner that the varnish could be present between the glass substrates to give a stacked structure having the above-mentioned first lamination configuration or second lamination configuration. Next, the varnish in the stacked structure is heated or hot air is applied thereto so as to evaporate the organic solvent, thereby forming an inner (or outer) resin composition layer. The inner (or outer) resin composition layer may be further semi-cured. In that manner, the laminate body can be produced.

### [Laminate Plate]

The laminate plate of the present invention contains at least two glass substrate layers and at least one inner cured resin layer and a metal foil existing between the adjacent two glass substrate layers, wherein the inner cured resin layer comprises a cured product of an inner resin composition that contains a thermosetting resin and an inorganic filler.

Preferably, the size of the laminate plate of the present invention is selected within a range where the width is from 10 mm to 1000 mm and the length is from 10 mm to 3000 mm (in case where the laminate plate is used as a roll, its length may be suitably applied thereto). More preferably, the size is within a range where the width is from 25 mm to 550 mm and the length is from 25 mm to 550 mm from the viewpoint of the handleability of the plate.

The thickness of the laminate plate of the present invention is selected preferably within a range of from 36 μm to 20 mm, depending on the use thereof. More preferably, the thickness of the laminate plate is from 50 to 1000 μm, even more preferably from 100 to 500 μm, still more preferably from 120 to 300 μm, further more preferably from 130 to 200 μm.

Preferably, the laminate plate is so designed that the inner resin composition layer and the outer resin composition layer of the above-mentioned laminate body form the inner cured resin layer and the outer cured resin layer thereof.

The details of the glass substrate layer, the inner resin composition layer and the outer resin composition layer are described in the section of the laminate body given hereinabove.

### <Inner Cured Resin Layer>

Preferably, the thickness of the inner cured resin layer is from 3 to 200 μm. When the thickness is at least 3 μm, then the laminate plate is prevented from cracking. When the thickness is at most 200 μm, then the thickness of the glass substrate layer could be relatively large and the laminate plate can therefore have a lowered thermal expansion coefficient and an increased elastic modulus. From these viewpoints, the thickness of the cured resin layer is more preferably from 3 to 150 μm, even more preferably from 3 to 100 μm, still more preferably from 3 to 50 μm, further more preferably from 3 to 40 μm.

However, the suitable range of the thickness of the cured resin layer may vary depending on the thickness of the glass substrate layer and the number of the layers, and the type of the cured resin layer and the number of the layers, and therefore the thickness of the cured resin layer can be suitably controlled.

The storage elastic modulus at 40° C. of the inner cured resin layer is preferably from 1 to 80 GPa. When the modulus is at least 1 GPa, then the glass substrate can be protected and the laminate plate can be prevented from cracking. When the modulus is at most 80 GPa, then the stress resulting from the difference in the thermal expansion coefficient between the glass substrate layer and the inner cured resin layer is retarded, and the laminate plate can be thereby prevented from warping and cracking. From these viewpoints, the storage elastic modulus of the inner cured resin layer is more preferably from 3 to 70 GPa, even more preferably from 5 to 60 GPa.

A metal foil of copper, aluminium, nickel or the like may be provided on one or both surfaces of the laminate plate. The metal plate may be any one for use for electric insulation materials, and is not specifically defined.

### <Outer Cured Resin Layer>

For enhancing the cracking resistance and the handleability (easiness in handling) of the glass substrate layer, the thickness of the outer cured resin layer is preferably at least 3 μm. On the other hand, for securing the low thermal expansion coefficient and the high elastic modulus of the laminate plate, the thickness of the outer cured resin layer is preferably at most 40 μm. From these viewpoints, the thickness of the outer cured resin layer is preferably from 3 to 40 μm, more preferably from 5 to 30 μm, even more preferably from 10 to 20 μm.

### <Glass Substrate Layer>

The details of the glass substrate layer are as described above.

Preferably, the glass substrate layer accounts for from 10 to 95% by volume relative to the entire laminate plate, more preferably from 15 to 90% by volume, even more preferably from 20 to 85% by volume, still more preferably from 40 to 80% by volume, further more preferably from 50 to 75% by volume, still further more preferably from 53 to 74% by volume. When the content of the glass substrate is at least 10% by volume, then it is advantageous for attaining low thermal expansivity and high elasticity; but on the contrary, when the content of the glass substrate is at most 95% by volume, then it is advantageous in point of the workability and the handleability (easiness in handling) of the laminate plate.

### <Characteristics of Laminate Plate>

The storage elastic modulus at 40° C. of the laminate plate is preferably from 10 to 70 GPa from the viewpoint of preventing the laminate plate from warping and cracking, more preferably from 20 to 60 GPa, even more preferably from 25 to 50 GPa, still more preferably from 25 to 45 GPa.

The mean thermal expansion coefficient of the laminate plate in a range of from 50 to 120° C. is preferably from 1 to 10 ppm/° C. from the viewpoint of preventing the laminate plate from warping and cracking, more preferably from 2 to 8 ppm/° C., even more preferably from 2 to 6 ppm/° C., still more preferably from 2 to 5 ppm/° C.

The mean thermal expansion coefficient of the laminate plate in a range of from 120 to 190° C. is preferably from 1 to 15 ppm/° C. from the viewpoint of preventing the laminate plate from warping and cracking, more preferably from 2 to 10 ppm/° C., even more preferably from 2 to 8 ppm/° C., still more preferably from 2 to 6 ppm/° C.

### <Proportion of Layers in Laminate Plate>

Preferably, in the present invention, the inner cured resin layer accounts for from 5 to 60% by volume relative to the entire laminate plate from the viewpoint of obtaining a laminate plate having a low thermal expansion coefficient and having a high elastic modulus, more preferably from 10 to 55% by volume, even more preferably from 10 to 50% by volume, still more preferably from 10 to 45% by volume.

The glass substrate layer in the present invention is as described above.

In case where the laminate plate has an outer cured resin layer, preferably, the outer cured resin layer accounts for from 1 to 35% by volume relative to the entire laminate plate, more preferably from 5 to 30% by volume, even more preferably from 10 to 25% by volume.

In case where the laminate plate has an adhesive layer, preferably, the adhesive for from 1 to 20% by volume relative to the entire laminate plate, more preferably from 2 to 15% by volume, even more preferably from 3 to 10% by volume.

### [Production Method for Laminate Plate]

The production method for the above-mentioned laminate plate is not specifically defined. Next, specific examples of the production method for the laminate plate are described.

### <Production Example for Laminate Plate by Thermal Curing>

In the laminate body obtained through the above-mentioned lamination, the support film is optionally peeled off, and then the inner resin composition layer and the outer resin composition layer are thermally cured to give a laminate plate.

The thermal curing condition is selected within a range of from 150° C. to 220° C. and from 20 minutes to 80 minutes, more preferably from 160° C. to 200° C. and from 30 minutes to 120 minutes. In case where a release-treated support film is used, the support film may be peeled off after thermal curing.

The method does not require pressurization in producing the laminate plate, in which, therefore, the laminate plate can be prevented from cracking during production.

### <Production Example According to Pressing Method>

The laminate plate of the present invention may also be produced according to a pressing method.

For example, the laminate body obtained through the above-mentioned lamination may be heated under pressure and cured according to a pressing method to give the laminate plate.

In addition, the adhesive film and/or the adhesive film body prepared by removing the support film and the protective film from the adhesive film may be stacked to a glass substrate, and heated under pressure and cured according to a pressing method to give the laminate plate.

Further, a B-stage one prepared by applying a varnish of the inner resin composition or the outer resin composition onto a support followed by drying it may be stacked to a glass substrate, and heated under pressure and cured according to a pressing method to give the laminate plate.

### [Multilayer Laminate Plate and its Production Method]

The multilayer laminate plate of the present invention contains multiple laminate plates, wherein at least one laminate plate is the laminate plate of the present invention.

The production method for the multilayer laminate plate is not specifically defined.

For example, a plurality of the above-mentioned laminate plates are multilayered via the adhesive film body prepared by removing the support film and the protective film from the above-mentioned adhesive film.

A plurality (for example, from 2 to 20) of the above-mentioned laminate bodies are stacked in layers and molded through lamination to give the multilayer laminate plate. Concretely, using a multistage press, a multistage vacuum press, a continuous molding machine, an autoclave molding machine or the like, the laminated bodies are molded at a temperature of from 100 to 250° C. or so, under a pressure of from 2 to 100 MPa or so, and for a heating time of from 0.1 to 5 hours or so.

### [Printed Wiring Board and its Production Method]

The printed wiring board of the present invention has the above-mentioned laminate plate or multilayer laminate plate, and a wiring formed on the surface of the laminate plate or the multilayer laminate plate.

Next described is the production method for the printed wiring board.

### <Formation of Via-Holes>

The laminate plate obtained by curing the above-mentioned laminate body having the second laminate configuration or the like laminate plate having a similar configuration is worked optionally according to a method of drilling, laser processing, plasma processing or a combination thereof, thereby forming via-holes or through-holes therein. As the laser, generally used is a carbon dioxide laser, a YAG laser, a UV laser, an excimer laser or the like. After the formation of via-holes, etc., the plate may be desmeared with an oxidizing agent. As the oxidizing agent, preferred here are permanganates (potassium permanganate, sodium permanganate, etc.), bichromates, ozone, hydrogen peroxide/sulfuric acid (that is, mixture of hydrogen peroxide and sulfuric acid) and nitric acid; and more preferred is an aqueous sodium hydroxide solution of potassium permanganate, sodium permanganate or the like (aqueous alkaline permanganate solution).

### <Formation of Conductor Layer>

Next, a conductor layer is formed on the outer cured resin layer on the surface of the laminate plate through dry plating or wet plating thereon.

For dry plating, employable is any known method of vapor deposition, sputtering, ion plating or the like.

In case of wet plating, first, the surface of the outer cured resin layer is roughened with an oxidizing agent of a permanganate (potassium permanganate, sodium permanganate, etc.), a bichromate, ozone, hydrogen peroxide/sulfuric acid, nitric acid or the like to thereby form irregular anchors thereon. As the oxidizing agent, especially preferred is an aqueous sodium hydroxide solution of potassium permanganate, sodium permanganate or the like (aqueous alkaline permanganate solution). The roughening treatment may function also as the above-mentioned desmearing treatment. Next, a conductor layer is formed according to a method of combination of electroless plating and electrolytic plating. A plating resist having an opposite pattern to the intended conductor layer may be formed, and the conductor layer may be formed by electroless plating alone.

In case where a support film having a metal foil on the surface thereof is used in the laminate body, the conductor layer formation step may be omitted.

### <Formation of Wiring Pattern>

As the subsequent patterning method, for example, employable here is any known subtractive method, a semi-additive method or the like.

### [Multilayer Printed Wiring Board and its Production Method]

As one embodiment of the above-mentioned printed wiring board, provided here is a multilayer printed wiring board by laminating multiple laminate plates each having a wiring pattern formed thereon as in the above.

For producing the multilayer printed wiring board of the type, a plurality of the above-mentioned laminated plates each with a wiring pattern formed thereon are laminated via the above-mentioned adhesive film body arranged therebetween for multilayer formation. Subsequently, through-holes or blind via-holes are formed in the board by drilling or laser processing, and then an interlaminar wiring is formed through plating or by the use of a conductive paste. According to the process, a multilayer printed wiring board is produced.

[Metal Foil-Attached Laminate Plate and Multilayer Laminate Plate, and their Production Method]

The above-mentioned laminate plate and multilayer laminate plate may be metal foil-attached laminate plate and multilayer laminate plate each having a metal plate of copper, aluminium, nickel or the like on one or both surfaces thereof.

The production method for the metal foil-attached laminate plate is not specifically defined. For example, as mentioned above, a metal foil may be used as the support film to produce a metal-foil attached laminate plate.

One or a plurality (for example, from 2 to 20) of the above-mentioned laminate plates produced through lamination or coating may be piled up, and a metal foil is arranged on one or both surfaces thereof, and these may be molded through lamination to give a metal foil-attached laminate plate.

Regarding the molding condition, any method of producing laminate plate or multilayer plate for electric insulating materials is usable here; and for example, using a multistage press, a multistage vacuum press, an automatic molding machine, an autoclave molding machine or the like, the laminate configuration may be molded at a temperature of from 100 to 250° C. or so, under a pressure of from 2 to 100 MPa or so, and for a heating time of from 0.1 to 5 hours or so.

### <Evaluation Method for Thermal Expansion Coefficient>

The thermal expansion coefficient of the laminate plate may be measured, using a thermal mechanical analysis (TMA), temperature-dependent 3D displacement analyzer (DIC, digital image correlation), a laser interferometer, etc.

### <Evaluation Method for Elastic Modulus>

The elastic modulus of the laminate plate may be determined by measuring, for example, the storage elastic modulus thereof using a wide-area viscoelasticity measuring device, and also by measuring the bending modulus thereof as a static elastic modulus. The bending elastic modulus may be measured according to a three-point bending test.

### EXAMPLES

Next, the present invention is described in more detail with reference to Examples and Comparative Examples; however, the present invention is not limited to these descriptions.

In Examples and Comparative Examples, “part” and “%” mean “part by mass” and “% by mass”, respectively.

FIG. 1 is a schematic cross-sectional view of explaining the production method of Example 1.

### Example 1

### Production of First Varnish

To 135.4 parts of a polyamide resin, Nippon Kayaku's “BPAM-155” (product name) dissolved in a dimethylacetamide solvent to have a concentration of 10%, added were 62.0 parts of an epoxy resin, Nippon Kayaku's “NC3000-H” (product name, concentration 100%) as a thermosetting resin, 23.5 parts of a triazine-containing phenolic novolak resin, DIC's “LA-1356-60P” (product name, concentration 60%) as a curing agent, 0.6 parts of 2-phenylimidazole, Shikoku Chemical Industry's “2PZ” (product name, concentration 100%) as a curing promoter, 8.8 parts of fumed silica, Nippon Aerosil's “AEROSIL R972” (product name, concentration 100%; mean particle diameter of primary particles, 16 nm; specific surface area according to BET method, 110±20 m²/g) as an inorganic filler, and 3.6 parts of a polyester-modified polydimethylsiloxane, BYK Chemie Japan's “BYK-310” (product name, concentration 25%) as an other component; and further, 314.3 parts of a dimethylacetamide solvent was added thereto. These were dissolved, mixed and processed with a bead mill to prepare a first varnish.

### Production of Second Varnish

31.8 parts of an epoxy resin, Nippon Kayaku's “NC3000-H” (product name, concentration 100%) as a thermosetting resin, 7.2 parts of a triazine-containing cresol-novolak, DIC's “LA-3018-50P” (product name, concentration 50%), 5.1 parts of a phosphorus-containing phenolic resin, Sanko's “HCA-HQ” (product name, concentration 100%) and 4.4 parts of a phenol-novolak, DIC's “TD2131” (concentration 100%) as curing agents, 0.1 parts of 1-cyanoethyl-2-phenylimidazolium trimellitate, Shikoku Chemical Industry's “2PZCNS-PW” (product name, concentration 100%) as a curing promoter, and 78.6 parts of a silica filler, Admafine Techno's “SO-C2” (product name, concentration 100%, mean particle diameter of primary particles, 500 nm; specific surface area according to BET method, 6.8 m²/g) as an inorganic filler which had been treated with an aminosilane coupling agent in a methyl isobutyl ketone solvent to have a solid concentration of 70%, were blended, and then 42.7 parts of methyl ethyl ketone was added thereto as an additional solvent. These were dissolved, mixed and processed with a bead mill to prepare a second varnish.

### Production of Adhesive Film 5a (Support Film 1/First Resin Composition Layer 2/Second Resin Composition Layer 4)

Using a polyethylene terephthalate film (PET film) having a thickness of 38 μm as a support film and using a comma coater, the varnish was applied onto the support film and dried. The amount of the varnish was so controlled that the coating thickness could be 5 μm. The drying temperature was 140° C., and the drying time was 3 minutes. Thus, the first resin composition layer 2 was formed on the support film 1 (FIG. 1(a)).

Next, using a comma coater, the second varnish was applied onto the side of the first resin composition layer 2, and dried. The amount of the varnish was so controlled that the coating thickness could be 40 μm (as so defined that the first resin composition layer 2 could be 5 μm, and the second resin composition layer 4 could be 35 μm). The drying temperature was 105° C., and the drying time was 1.2 minutes. Thus, the second resin composition layer 4 was formed to give the adhesive film 5a having a width of 270 mm (FIG. 1(b)).

### Production of Laminate Plate 8a (Glass Substrate Layer/Second Inner Cured Resin Layer/First Inner Cured Resin Layer/First Inner Cured Resin Layer/Second Inner Cured Resin Layer/Glass Substrate Layer)

As the glass substrate layer 6, used here was an ultrathin glass film, Nippon Electric Glass's “OA-10G” (product name, thickness 50 μm 250 mm×250 mm). On one surface of the glass substrate layer 6, the adhesive film 5a was so arranged that its second resin composition layer 4 could face the glass substrate layer 6, and laminated using a batch-type vacuum pressure laminator “MVLP-500” (Meiki's product name) (FIG. 1(c), (d)). In this stage, the vacuum degree was at most 30 mmHg, the temperature was 90° C., and the pressure was 0.5 MPa. In that manner, obtained here was an intermediate laminate body 7a of glass substrate layer 6/second cured resin layer 4/first cured resin layer 2/support film 1.

Two such intermediate laminate bodies 7a were produced. After cooled to room temperature, the support film was peeled off from both the two. These were so arranged that the first resin composition layer 2 of one, which had been exposed out through the peeling of the support film, could face that of the other, and laminated using a batch-type vacuum pressure laminator “MVLP-500” (Meiki's product name) (FIG. 1(e)). In this stage, the vacuum degree was at most 30 mmHg, the temperature was 65° C., and the pressure was 0.5 MPa.

After cooled to room temperature, this was cured in dry air at 180° C. for 60 minutes. Thus cured, the first resin composition layer 2 and the second resin composition layer 4 formed a first inner cured resin layer 2a and a second inner cured resin layer 4a, respectively. In that manner, a six-layered laminate plate 8a (glass substrate layer 6/second inner cured resin layer 4a/first inner cured resin layer 2a/first inner cured resin layer 2a/second inner cured resin layer 4a/glass substrate layer) was obtained (FIG. 1(f)).

### Example 2

### Production of Adhesive Film 5b (Support Film/First Resin Composition Layer/Second Resin Composition Layer)

An adhesive film 5b was produced according to the same process as that for the adhesive film 5a in Example 1, except that the coating thickness of the varnish was changed from 40 μm to 20 μm (as so defined that the first resin composition layer 2 could be 5 μm, and the second resin composition layer 4 could be 15 μm).

### Production of Laminate Plate 8b (First Outer Cured Resin Layer/Second Outer Cured Resin Layer/Glass Substrate Layer/First Inner Cured Resin Layer/Second Inner Cured Resin Layer/Glass Substrate Layer/Second Outer Cured Resin Layer/First Outer Cured Resin Layer)

As the glass substrate layer 6, used here was an ultrathin glass film, Nippon Electric Glass's “OA-10G” (product name, thickness 50 μm; 250 mm×250 mm). The above-mentioned adhesive film 5a was so arranged that the second resin composition layer 4 thereof could face one surface of the glass substrate layer 6, and the above-mentioned adhesive film 5b was so arranged that the second resin composition layer 4 thereof could face the other surface of the glass substrate 6, thereby preparing a stacked structure (FIG. 2(a)); and the stacked structure was laminated using a batch-type vacuum pressure laminator “MVLP-500” (Meiki's product name) to give an intermediate laminate body 7b (FIG. 2(b)). In this stage, the vacuum degree was at most 30 mmHg, the temperature was 90° C., and the pressure was 0.5 MPa.

After cooled to room temperature, the support film 1 on the side of the adhesive film 5a in the intermediate laminate body 7b was peeled off. One other sheet of the glass substrate layer 6 (thickness 50 μm, 250×250 mm) was prepared, and this was so arranged that the first resin composition layer 2, which had been exposed out through the peeling of the support film 1, could face one surface of the glass substrate layer 6. The adhesive film 5b was so arranged that the second resin composition layer 4 thereof could face the other surface of the glass substrate layer 6. The stacked structure was laminated using a batch-type vacuum pressure laminator “MVLP-500” (Meiki's product name) (FIG. 2(b)). In this stage, the vacuum degree was at most 30 mmHg, the temperature was 65° C., and the pressure was 0.5 MPa.

After cooled to room temperature, the support film 1 was peeled off, and the intermediate laminate was cured in dry air at 180° C. for 60 minutes to give an eight-layered laminate plate 8b (first outer cured resin layer/second outer cured resin layer/glass substrate layer/first inner cured resin layer/second inner cured resin layer/glass substrate/second outer cured resin layer/first outer cured resin layer) (FIG. 2(c)).

### Example 3

### Production of Third Varnish

To 135.4 parts of a polyamide resin, Nippon Kayaku's “BPAM-155” (product name) dissolved in a dimethylacetamide solvent to have a concentration of 10%, added were 62.0 parts of an epoxy resin, Nippon Kayaku's “NC3000-H” (product name, concentration 100%) as a thermosetting resin, 23.5 parts of triazine-containing phenolic novolak resin, DIC's “LA-1356-60P” (product name, concentration 60%) as a curing agent, 0.6 parts of 2-phenylimidazole, Shikoku Chemical Industry's “2PZ” (product name, concentration 100%) as a curing promoter, 4.8 parts of fumed silica, Nippon Aerosil's “AEROSIL R972” (product name, concentration 100%) as an inorganic filler, and 1.7 parts of a polyester-modified polydimethylsiloxane, BYK Chemie Japan's “BYK-310” (product name, concentration 25%) as an other component; and further, 66.3 parts of a dimethylacetamide solvent was added thereto. Subsequently, using a disperser (Nanomizer, product name, by Yoshida Kikai), these were processed to give a uniform third varnish.

### Production of Adhesive Film 5c, 5d (Support Film 1/Resin Composition Layer 4)

The resin composition layer 4 was formed on the support film 1 to give an adhesive film 5c, 5d. The method is as follows: Using a comma coater, the third varnish was applied on the treated side of a release-treated polyethylene terephthalate (PET) film (PET-38X, by Lintec, product name) serving as a support film in such a manner that the thickness thereof after dried could be 10 μm, and then dried at 140° C. for 5 minutes thereby producing the adhesive film 5c comprising the resin composition layer 4 and the support film 1. In the same manner, the third varnish was applied in order that the coating thickness after dried could be 20 μm, thereby producing the adhesive film 5d having a width of 270 mm.

### Production of Laminate Plate (Outer Cured Resin Layer/Glass Substrate Layer/Inner Cured Resin Layer/Glass Substrate Layer/Outer Cured Resin Layer)

As the glass substrate layer 6, used here was an ultrathin glass film, Nippon Electric Glass's “OA-10G” (product name, thickness 50 μm; 250 mm×250 mm). The above-mentioned adhesive film 5c was so arranged that the resin composition layer 4 thereof could face one surface of the glass substrate layer 6, and the above-mentioned adhesive film 5d was so arranged that the resin composition layer 4 thereof could face the other surface of the glass substrate layer 6, thereby giving a stacked structure (FIG. 3(a)). The stacked structure was laminated using a batch-type vacuum pressure laminator “MVLP-500” (Meiki's product name) to give an intermediate laminate body 7c (FIG. 3(b)). In this stage, the vacuum degree was at most 30 mmHg, the temperature was 120° C., and the pressure was 0.5 MPa.

After cooled to room temperature, the support film 1 on the side of the adhesive film 5d in the intermediate laminate body 7c was peeled off. One other sheet of the glass substrate layer 6 (thickness 50 μm, 250×250 mm) was prepared, and this was so arranged that the resin composition layer 4, which had been exposed out through the peeling of the support film 1, could face one surface of the glass substrate layer 6. The adhesive film 5c was so arranged that the resin composition layer 4 thereof could face the other surface of the glass substrate layer 6 (FIG. 3(b)). The stacked structure was laminated using a batch-type vacuum pressure laminator “MVLP-500” (Meiki's product name). In this stage, the vacuum degree was at most 30 mmHg, the temperature was 100° C., and the pressure was 0.5 MPa.

After cooled to room temperature, the support film was peeled off, and curing was effected in dry air at 180° C. for 60 minutes to thereby give a five-layered laminate plate 8c (outer cured resin layer/glass substrate layer/inner cured resin layer/glass substrate layer/outer cured resin layer) (FIG. 3(c)).

### Comparative Example 1

### Production of Laminate Plate (First Outer Cured Resin Layer/Second Outer Cured Resin Layer/Glass Substrate Layer/Second Outer Cured Resin Layer/First Outer Cured Resin Layer)

As the glass substrate, used here was an ultrathin glass film, Nippon Electric Glass's “OA-10G” (product name, thickness 100 μm; 250 mm×250 mm). On both surfaces of the glass substrate, the adhesive film 5a was so arranged that the second cured resin layer 4 thereof could face the glass substrate, and laminated using a batch-type vacuum pressure laminator “MVLP-500” (Meiki's product name). In this stage, the vacuum degree was at most 30 mmHg, the temperature was 90° C., and the pressure was 0.5 MPa.

After cooled to room temperature, the support film was peeled off, and this was cured in dry air at 180° C. for 60 minutes to give a five-layered laminate plate (first outer cured resin layer/second outer cured resin layer/glass substrate layer/second outer cured resin layer/first outer cured resin layer).

### Comparative Example 2

### Production of Laminate Plate (Outer Cured Resin Layer/Glass Substrate Layer/Outer Cured Resin Layer)

As the glass substrate, used here was an ultrathin glass film, Nippon Electric Glass's “OA-10G” (product name, thickness 100 μm; 250 mm×250 mm). On both surfaces of the glass substrate, the adhesive film 5d was so arranged that the cured resin layer 4 thereof could face the glass substrate, and laminated using a batch-type vacuum pressure laminator “MVLP-500” (Meiki's product name). In this stage, the vacuum degree was at most 30 mmHg, the temperature was 120° C., and the pressure was 0.5 MPa.

After cooled to room temperature, the support film was peeled off, and this was cured in dry air at 180° C. for 60 minutes to give a three-layered laminate plate (outer cured resin layer/glass substrate layer/outer cured resin layer).

### Reference Example 1

Next, a laminate plate using a prepreg, which is a commonly-used laminate plate for semiconductor packages or printed wiring boards, is produced as follows:

### <Production of Solution of Unsaturated Maleimide Group-Having Resin Composition>

In a heatable and coolable reactor having a capacity of 2 liters and equipped with a thermometer, a stirrer and a moisture meter provided with a reflux condenser tube, 69.10 g of 4,4′-bis(4-aminophenoxy)biphenyl, 429.90 g of bis(4-maleimidophenyl)sulfone, 41.00 g of p-aminophenol and 360.00 g of propylene glycol monomethyl ether were put, and reacted at the reflux temperature for 2 hours, thereby giving a solution of a resin composition having an acidic substituent and an unsaturated maleimide group.

### <Production of Thermosetting Resin Composition-Containing Varnish>

The following were used here.

(1) The above-mentioned, unsaturated maleimide group-having resin composition solution, as a curing agent (A);
(2) A bifunctional naphthalene-type epoxy resin [DIC's product name, HP-4032D] as a thermosetting resin (B);
(3) An isocyanate-masked imidazole [Daiichi Kogyo Seiyaku's product name, G8009L] as a modified imidazole (C),
(4) A molten silica [Admatec's product name, SC2050-KC; concentration 70%; mean particle size of primary particles, 500 nm; specific surface area according to BET method, 6.8 m²/g] as an inorganic filler (D),
(5) A phosphorus-containing phenolic resin [Sanko Chemical's product name, HCA-HQ, phosphorus content 9.6% by mass] as a flame retardance-imparting, phosphorus-containing compound (E),
(6) A crosslinked acrylonitrile-butadiene rubber (NBR) particles [JSR's product name, XER-91] as a compound (F) that enables chemical roughening, and
(7) Methyl ethyl ketone as a diluting solvent.

These were mixed in the blend ratio (part by mass) as shown in Table 1 to prepare a uniform varnish (G) having a resin content (total of resin components) of 65% by mass.

TABLE 1

| | part by mass |
|---|---|
| Curing Agent (A) | 50 |
| Thermosetting Resin (B) | 49.5 |
| Modified Imidazole (C) | 0.5 |
| Inorganic Filler (D) | 40 |
| Phosphorus-Containing Compound (E) | 3 |
| Compound (F) | 1 |

### [Production of Prepreg of Thermosetting Resin Composition]

The above-mentioned varnish (G) was applied onto E-glass cloths each having a different thickness by dipping, and then dried under heat at 160° C. for 10 minutes to give prepregs (thickness 100 μm, 250 mm×250 mm). Regarding the type of the E-glass cloth, used here was Asahi Kasei E-Materials' IPC standard 2116. The resin content in the prepregs prepared here was 50% by mass. Three of the prepregs were combined, an electrolytic copper foil having a thickness of 12 μm was arranged on and below these, and pressed under a pressure of 3.0 MPa at a temperature of 235° C. for 120 minutes to give a copper-clad laminate plate.

### [Measurement]

The laminate plates obtained in the above-mentioned Examples, Comparative Example and Reference Example were analyzed and evaluated for the properties thereof, according to the methods mentioned below.

### (1) Measurement of Thermal Expansion Coefficient

A test piece of 4 mm×30 mm was cut out of the laminate plate. In case where a copper-clad laminate plate is tested, the plate was dipped in a copper etching solution to remove the copper foil, and the test piece was cut out of it.

Using a TMA tester (by DuPont, TMA2940), the thermal expansion behavior of the test piece at lower than Tg was observed and evaluated. Concretely, the test piece was heated at a heating rate of 5° C./min, then within a measurement range of from 20 to 200° C. in the 1st run, and from −10 to 280° C. in the 2nd run, this was analyzed according to a tensile method under a load of 5 g and with a chuck distance of 10 mm. The mean thermal expansion coefficient of the sample within a range of from 50 to 120° C. and within a range of from 120 to 190° C. was determined. The results are shown in Table 2.

### (2) Measurement of Storage Elastic Modulus

A test piece of 5 mm×30 mm was cut out of the laminate plate. In case where a copper-clad laminate plate is tested, the plate was dipped in a copper etching solution to remove the copper foil, and the test piece was cut out of it.

Using a wide-area viscoelasticity meter (Rheology's DVE-V4 Model), the test piece was analyzed for the storage elastic modulus at 40° C. with a span distance of 20 mm, at a frequency of 10 Hz and under the condition of a vibration displacement of from 1 to 3 μm (stop excitation). The results are shown in Table 2.

TABLE 2

| | | | Thermal Expansion Coefficient | | Elastic Modulus |
|---|---|---|---|---|---|
| | | Proportion of Glass | (ppm/° C.) | | (GPa) |
| | Configuration of Laminate Plate | (% by volume) | 50-120° C. | 120-190° C. | 40° C. |
| Example 1 | Glass Substrate Layer: 50 μm | 56 | 3.5 | 2.5 | 42.0 |
| | Inner Cured Resin Layer: 80 μm | | | | |
| | Glass Substrate Layer: 50 μm | | | | |
| Example 2 | Outer Cured Resin Layer: 20 μm | 56 | 3.8 | 2.5 | 38.5 |
| | Glass Substrate Layer: 50 μm | | | | |
| | Inner Cured Resin Layer: 40 μm | | | | |
| | Glass Substrate Layer: 50 μm | | | | |
| | Outer Cured Resin Layer: 20 μm | | | | |
| Example 3 | Outer Cured Resin Layer: 10 μm | 71 | 2.7 | 3.0 | 45.0 |
| | Glass Substrate Layer: 50 μm | | | | |
| | Inner Cured Resin Layer: 20 μm | | | | |
| | Glass Substrate Layer: 50 μm | | | | |
| | Outer Cured Resin Layer: 10 μm | | | | |
| Comparative | Outer Cured Resin Layer: 40 μm | 56 | 3.9 | 2.5 | 32.4 |
| Example 1 | Glass Substrate Layer: 100 μm | | | | |
| | Outer Cured Resin Layer: 40 μm | | | | |
| Comparative | Outer Cured Resin Layer: 20 μm | 71 | 2.7 | 3.0 | 42.0 |
| Example 2 | Glass Substrate Layer: 100 μm | | | | |
| | Outer Cured Resin Layer: 20 μm | | | | |
| Reference | Prepreg: 100 μm | 0 | 13.1 | 15.3 | 24.7 |
| Example 1 | Prepreg: 100 μm | | | | |
| | Prepreg: 100 μm | | | | |

As obvious from Table 2, Examples 1 to 3 of the present invention are excellent in low thermal expansivity at 50 to 120° C. and in high elasticity at 40° C. In particular, the laminate plates of the present invention have a high elastic modulus. In addition, it is apparent that, within a high-temperature range (120 to 190° C.), the thermal expansion coefficient of Reference Example 1 was higher than that in a low-temperature range (50 to 120° C.), but Examples have low thermal expansivity on the same level both in the high-temperature range and in the low-temperature range. Accordingly, Examples of the present invention maintain low thermal expansivity not only in a low-temperature range but also in a high-temperature range.

### DESCRIPTION OF REFERENCE NUMERALS AND SIGNS

1 Support Film
2 First Resin Composition Layer
2a First Inner Cured Resin Layer
4 Second Resin Composition Layer
4a Second Inner Cured Resin Layer
5a, 5b, 5c, 5d Adhesive Film
6 Glass Substrate Layer
7a, 7b, 7c Intermediate Laminate Body
8a, 8b, 8c Laminate Plate

1. A laminate body containing at least two glass substrate layers and at least one inner resin composition layer existing between the adjacent two glass substrate layers, wherein the inner resin composition layer comprises an inner resin composition that contains a thermosetting resin and an inorganic filler.

2. The laminate body according to claim 1, wherein the thickness of the glass substrate layer is from 30 to 200 μm.

3. The laminate body according to claim 1, wherein an outermost surface layer of the laminate body and an outermost back layer of the laminate body are the glass substrate layers.

4. The laminate body according to claim 1, which has an outer resin composition layer on the more surface side than the glass substrate layer on the outermost surface side and on the more back side than the glass substrate layer on the outermost back side of at least the two glass substrate layers.

5. The laminate body according to claim 4, wherein the outer resin composition layer has a thickness of from 3 to 40 μm.

6. The laminate body according to claim 1, wherein the thermosetting resin is one or more selected from an epoxy resin, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin and a melamine resin.

7. The laminate body according to claim 1, wherein the inorganic filler is one or more selected from silica, alumina, talc, mica, aluminium hydroxide, magnesium hydroxide, calcium carbonate, aluminium borate and borosilicate glass.

8. A laminate plate containing at least two glass substrate layers and at least one inner cured resin layer existing between the adjacent two glass substrate layers, wherein the inner cured resin layer comprises a cured product of an inner resin composition that contains a thermosetting resin and an inorganic filler.

9. The laminate plate according to claim 8, which has a storage elastic modulus at 40° C. of from 10 GPa to 70 GPa.

10. The laminate plate according to claim 8, which is obtained by heating a laminate body containing at least two glass substrate layers and at least one inner resin composition layer existing between the adjacent two glass substrate layers, wherein the inner resin composition layer comprises the inner resin composition that contains the thermosetting resin and the inorganic filler.

11. A multilayer laminate plate containing multiple laminate plates, wherein at least one laminate plate is the laminate plate of claim 8.

12. A printed wiring board having the laminate plate of claim 8 and a wiring provided on the surface of the laminate plate.

13. A printed wiring board having the multilayer laminate plate of claim 11 and a wiring provided on the surface of the multilayer laminate plate.

14. A method for producing the laminate plate of claim 8, which comprises a cured resin layer forming step of forming a cured resin layer on the surface of a glass substrate.

15. The method for producing a laminate plate according to claim 14, wherein the cured resin layer forming step is a step of applying the resin composition onto the glass substrate followed by drying and curing the resin composition.

16. The method for producing a laminate plate according to claim 14, wherein the cured resin layer forming step is a step of laminating a film of the resin composition onto the glass substrate by the use of a vacuum laminator or a roll laminator followed by curing the film.

17. The method for producing a laminate plate according to claim 14, wherein the cured resin layer forming step is a step of arranging a film of the resin composition on the glass substrate followed by pressing and curing the film.
